(19) United States
(12) Patent Application Publication
(10) Pub. No.: US 2026/0243852 A1
(43) Pub. Date: Aug. 20, 2026

(54) MAGNETORESISTIVE ELEMENT AND MAGNETIC SENSOR HAVING SAME

(71) Applicant: TDK Corporation, Tokyo (JP)

(72) Inventor: Hiroki OMURA, Tokyo (JP)

(21) Appl. No.: 19/416,190

(22) Filed: Dec. 11, 2025

(30) Foreign Application Priority Data
Feb. 18, 2025 (JP) 2025-024046

(51) Int. Cl. G01R 33/09

(52) U.S. Cl. CPC G01R 33/093

(57) ABSTRACT

A magnetoresistive element comprises a magnetically free layer (45), a magnetically pinned layer (43), and a nonmagnetic layer (44) arranged in a first direction. The magnetically free layer (45) is magnetized in a vortex shape. The magnetization direction of the magnetically free layer (45) is variable according to external magnetic field. The magnetization direction of the magnetically pinned layer (43) is fixed in the first direction (Z). The nonmagnetic layer (44) is located between the magnetically free layer (45) and the magnetically pinned layer (43). At least a part of the centerline (44A) of the nonmagnetic layer (44) has a convexo-concave shape (46) in a cross section parallel to the first direction (Z).

### FIELD

This application claims the benefit of Japanese Priority Patent Application No. 2025-024046 filed on February 18, 2025, the entire contents of which are incorporated herein by reference.

The present disclosure relates to a magnetoresistive element and a magnetic sensor having same.

### BACKGROUND

JP2023-553931A describes a magnetoresistive element having a magnetically free layer magnetized in a vortex shape in the absence of an external magnetic field (zero magnetic field state) and a magnetically pinned layer whose magnetization direction is fixed in the film thickness direction. In the zero magnetic field state, the center of the vortex shape of the magnetically free layer is magnetized in the film thickness direction, and the magnetic moment of the magnetically free layer is not zero. In other words, the magnetic moment of the magnetically free layer produces an offset.

### SUMMARY

A magnetoresistive element of the present disclosure comprises a magnetically free layer, a magnetically pinned layer, and a nonmagnetic layer arranged in a first direction. The magnetically free layer is magnetized in a vortex shape, the magnetization direction of the magnetically free layer is variable according to external magnetic field, and the magnetization direction of the magnetically pinned layer is fixed in the first direction. The nonmagnetic layer is located between the magnetically free layer and the magnetically pinned layer, and at least a part of the centerline of the nonmagnetic layer has a convexo-concave shape in a cross section parallel to the first direction.

### BRIEF DESCRIPTION OF DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a schematic side view of a magnetic sensor according to one example embodiment of the present disclosure.

FIG. 2 is a schematic oblique view of a magnetically free layer, a nonmagnetic layer, and a first magnetically pinned layer.

FIGS. 3A–3B are schematic views showing the relationship between an external magnetic field and the magnetic moment of the magnetically free layer.

FIG. 4 shows a cross-sectional view of the nonmagnetic layer in a cross section parallel to the Z-direction.

FIGS. 5A–5B are schematic views showing the principles of generating a cancelling magnetic field.

FIGS. 6A–6B are drawings showing a first method for determining shape characteristic values of a convexo-concave shape at the centerline of the nonmagnetic layer.

FIGS. 7A–7B are drawings showing a second method for determining shape characteristic values of a convexo-concave shape at the centerline of the nonmagnetic layer.

FIGS. 8A–8B are drawings showing a third method for determining shape characteristic values of a convexo-concave shape at the centerline of the nonmagnetic layer.

FIGS. 9A–9B are drawings showing a fourth method for determining shape characteristic values of a convexo-concave shape at the centerline of the nonmagnetic layer.

### DETAILED DESCRIPTION

An offset of the magnetic moment of a magnetically free layer may affect the detectable magnetic field strength of a magnetoresistive element. One of the objects of the present disclosure is to provide a magnetoresistive element having a magnetically free layer magnetized in a vortex shape and a magnetically pinned layer whose magnetization direction is fixed in the film thickness direction, and in which the offset of the magnetic moment of the magnetically free layer is suppressed in the absence of an external magnetic field.

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

Example embodiments of the present disclosure will be described with reference to the drawings. In the following description and drawings, the film thickness direction of magnetically free layer 45 or the direction in which first magnetically pinned layer 43, nonmagnetic layer 44, and magnetically free layer 45 are arranged (stacked) is referred to as the first direction (Z-direction). The direction from substrate 2 to magnetically free layer 45 is referred to as the +Z- direction, and the direction from magnetically free layer 45 to substrate 2 is referred to as the –Z-direction. When the +Z-direction and –Z-direction need not be distinguished, these directions may be referred to as the Z-direction. One direction orthogonal to the +Z-direction is referred to as the X-direction. The X-direction is shown in the drawings for convenience but is not limited to the direction shown.

### Overall Structure of Magnetic Sensor 1

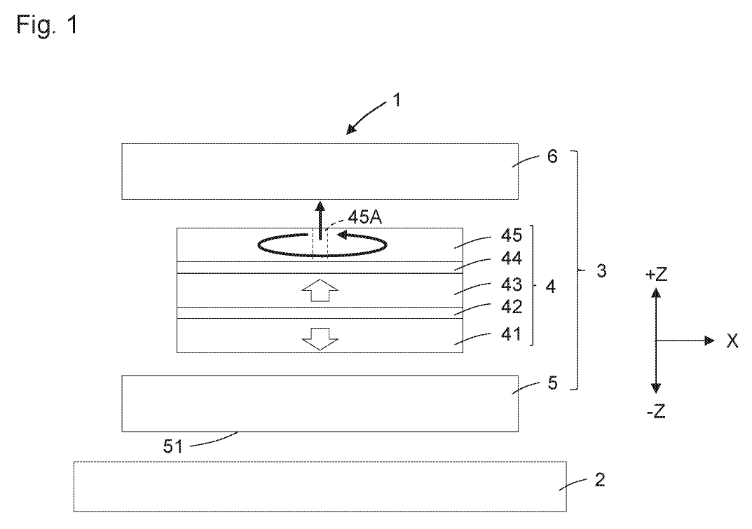

FIG. 1 is a schematic side view of magnetic sensor 1 according to one example embodiment of the present disclosure. The white arrows indicate the magnetization directions of first magnetically pinned layer 43 and second magnetically pinned layer 41. The bold lines with arrows indicate the magnetization directions of magnetically free layer 45 in the absence of an external magnetic field (hereinafter referred to as the zero magnetic field state). The external magnetic field is the magnetic field to be detected and does not include the magnetic field generated inside magnetoresistive element 3. In this example embodiment, magnetic sensor 1 may include substrate 2 and magnetoresistive element 3. Magnetoresistive element 3 may include magnetic field detector 4 and first and second electrode layers 5 and 6 that supply a sense current. First and second electrode layers 5 and 6 may sandwich magnetic field detector 4 in the Z-direction, and first electrode layer 5 may be located between substrate 2 and magnetic field detector 4. Although not shown in the drawings, other layers can be provided between first electrode layer 5 and substrate 2, and first electrode layer 5 may be separated from substrate 2. Substrate 2 may be formed of silicon or the like. First electrode layer 5 and second electrode layer 6 may be formed of laminated films or the like made of conductors such as Ta, Cu, and Ru.

### Structure of Magnetic Field Detector 4

Magnetic field detector 4 may comprise magnetically free layer 45, nonmagnetic layer 44, first magnetically pinned layer 43, intermediate layer 42, and second magnetically pinned layer 41. These layers 41–45 may be arranged in the order of second magnetically pinned layer 41, intermediate layer 42, first magnetically pinned layer 43, nonmagnetic layer 44, and magnetically free layer 45 in the +Z-direction from first electrode layer 5 to second electrode layer 6, and adjacent layers may be in contact with each other. These layers 41–45 may also be stacked in the opposite direction. Specifically, these layers 41–45 may be arranged in the order of second magnetically pinned layer 41, intermediate layer 42, first magnetically pinned layer 43, nonmagnetic layer 44, and magnetically free layer 45 in the –Z-direction from second electrode layer 6 to first electrode layer 5. Magnetic field detector 4 may be electrically connected to first and second electrode layers 5 and 6. A conductive layer such as a base layer (not shown) may be provided between magnetic field detector 4 and first electrode layer 5, and a conductive layer such as a cap layer (not shown) may be provided between magnetic field detector 4 and second electrode layer 6.

Magnetically free layer 45 is a magnetic layer whose magnetization direction is variable according to an external magnetic field. Magnetically free layer 45 can be formed of, for example, CoFe, CoFeB, and NiFe. In a zero magnetic field state, magnetically free layer 45 may be magnetized in a vortex shape in a plane perpendicular to the Z-direction. The magnetization state of magnetically free layer 45 in the zero magnetic field state may depend on the balance between the exchange energy and the static magnetization energy of magnetically free layer 45. In general, a vortex-shaped magnetization state is more likely to occur when the saturation magnetization is large. In the zero magnetic field state, the center of the vortex (hereinafter referred to as core 45A) is located at generally the center of magnetically free layer 45, and the magnetization direction forms concentric circles around core 45A. In general, in a magnetically free layer that does not form a vortex magnetization state in the zero magnetic field state, the tendency for magnetization to incline with respect to a magnetic field in the Z-direction changes and the sensitivity of the magnetic sensor output tends to fluctuate when a magnetic field in an in-plane direction (X-direction) is applied. In a magnetically free layer that forms a vortex magnetization state, the tendency for magnetization to incline with respect to a magnetic field in the Z-direction does not easily change when a magnetic field in an in-plane direction (X-direction) is applied, and fluctuation in sensitivity is thus suppressed.

Nonmagnetic layer 44 may be located between magnetically free layer 45 and first magnetically pinned layer 43. Nonmagnetic layer 44 may be formed of an insulating layer such as MgO or Al₂O₃. Magnetoresistive element 3 in this example embodiment may operate as a tunnel magnetoresistive element (TMR element). Nonmagnetic layer 44 may be formed of a nonmagnetic metal layer such as copper or silver, in which case magnetoresistive element 3 may operate as a giant magnetoresistive element (GMR element). A TMR element tends to provide higher output than a GMR element.

First magnetically pinned layer 43 is a magnetic layer whose magnetization direction is fixed in the Z-direction with respect to an external magnetic field. In this example embodiment, first magnetically pinned layer 43 may be magnetically coupled to second magnetically pinned layer 41 by synthetic antiferromagnetic coupling through intermediate layer 42. The magnetization direction of first magnetically pinned layer 43 is fixed in the opposite direction to that of second magnetically pinned layer 41. First magnetically pinned layer 43 and second magnetically pinned layer 41 can be formed of multilayers of Co film and Pt film, or of materials with strong perpendicular magnetic anisotropy, such as multilayers of Co film and Pd film or multilayers of Co film and Ni film. Intermediate layer 42 may be formed of a nonmagnetic metal that causes RKKY (Ruderman-Kittel-Kasuya-Yosida) coupling, such as ruthenium. Because the magnetization directions of first magnetically pinned layer 43 and second magnetically pinned layer 41 may be directed in opposite directions, the leakage magnetic field applied from first magnetically pinned layer 43 to magnetically free layer 45 can be suppressed. In FIG. 1, first magnetically pinned layer 43 may be magnetized in the +Z-direction and second magnetically pinned layer 41 may be magnetized in the –Z-direction. However, first magnetically pinned layer 43 may be magnetized in the –Z-direction and second magnetically pinned layer 41 may be magnetized in the +Z-direction. The technology of the present disclosure is not limited to the configuration described above, and in some cases, a magnetic layer that does not contain synthetic antiferromagnetic coupling may be used as the magnetically pinned layers.

The magnetization direction of magnetically free layer 45 is variable according to external magnetic field. Namely, when an external magnetic field including a component in the Z-direction is applied to magnetically free layer 45, the magnetization direction of magnetically free layer 45 may tilt in the Z-direction. This tilting may change the angle between the magnetization direction of magnetically free layer 45 and the magnetization direction of first magnetically pinned layer 43, and the electrical resistance of magnetic field detector 4 may change due to the magnetoresistive effect. By detecting the change in electrical resistance of magnetic field detector 4, the intensity of the Z-direction component of the external magnetic field can be measured. In this way, magnetic sensor 1 of this example embodiment may detect the magnetic field in the Z-direction.

Although not shown in the drawings, magnetic field detector 4 may include an antiferromagnetic layer. The antiferromagnetic layer can be provided on the side of second magnetically pinned layer 41 that is opposite the side of intermediate layer 42 and may be in contact with second magnetically pinned layer 41. The antiferromagnetic layer can be formed of, for example, IrMn, PtMn, or FeRh. The antiferromagnetic layer may be exchange-coupled with second magnetically pinned layer 41. When the antiferromagnetic layer is provided, the magnetization direction of second magnetically pinned layer 41 can be fixed more strongly than when the antiferromagnetic layer is not provided. For example, even if the magnetization direction of second magnetically pinned layer 41 reverses due to the application of a strong magnetic field, the magnetization direction of second magnetically pinned layer 41 returns to its original direction by exchange coupling with the antiferromagnetic layer when a zero magnetic field condition occurs. The magnetization direction of second magnetically pinned layer 41 in the zero magnetic field state may therefore be easily stabilized when an antiferromagnetic layer is provided, and reversal of output is unlikely to occur.

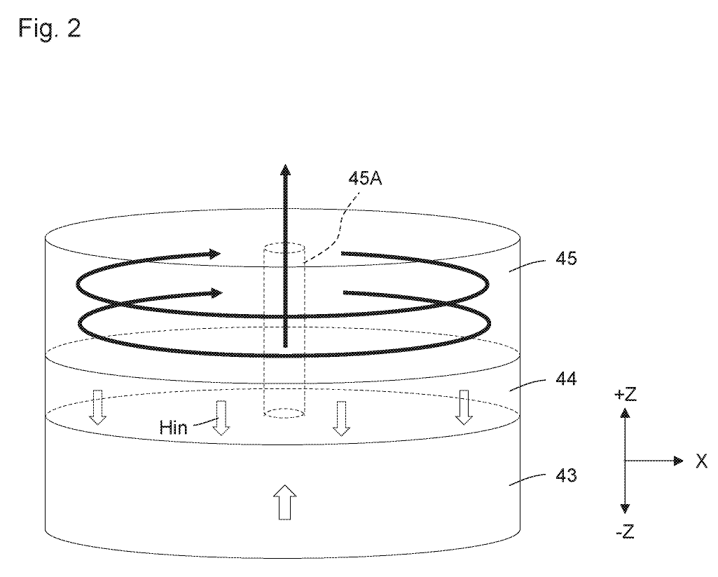

FIG. 2 shows a schematic oblique view of magnetically free layer 45, nonmagnetic layer 44 and first magnetically pinned layer 43. The cross-sectional shape of these layers 43–45 at each position in the Z-direction may be circular or approximately circular. Vortex-shaped magnetization states are more likely to occur in magnetically free layers that are rotationally symmetric in the Z-direction. The cross-sectional shape of magnetically free layer 45, nonmagnetic layer 44, and first magnetically pinned layer 43 as viewed in the Z-direction may therefore be not only circular but also elliptical or polygonal, such as a regular hexagon, square, or octagon.

### Magnetic Properties of Magnetically Free Layer 45

As described above, magnetically free layer 45 may be magnetized in a vortex shape, and core 45A may be magnetized in a direction parallel to, for example, the Z-direction. In general, whether the magnetization direction of core 45A of magnetically free layer 45 is directed in the +Z-direction or the –Z-direction is randomly determined. For example, even in a single wafer in which many magnetoresistive elements 3 have been formed, the magnetization direction of core 45A may be different for each magnetoresistive element 3. In this example embodiment, the magnetization direction of core 45A may be uniquely determined by applying a magnetic field in the +Z- or –Z-direction in advance. In other words, by applying a magnetic field in the +Z-direction to magnetoresistive element 3 and then stopping the application of the magnetic field, the magnetization direction of core 45A in the zero magnetic field state may be directed in the +Z-direction. By applying a magnetic field in the –Z-direction and then stopping the application of the magnetic field, the magnetization direction of core 45A in the zero magnetic field state may be directed in the –Z-direction. No difference in performance may occur regardless of the direction in which the magnetization direction of core 45A is oriented. In this example embodiment, for the purpose of explanation, the magnetization direction of core 45A is assumed to be directed in the +Z-direction.

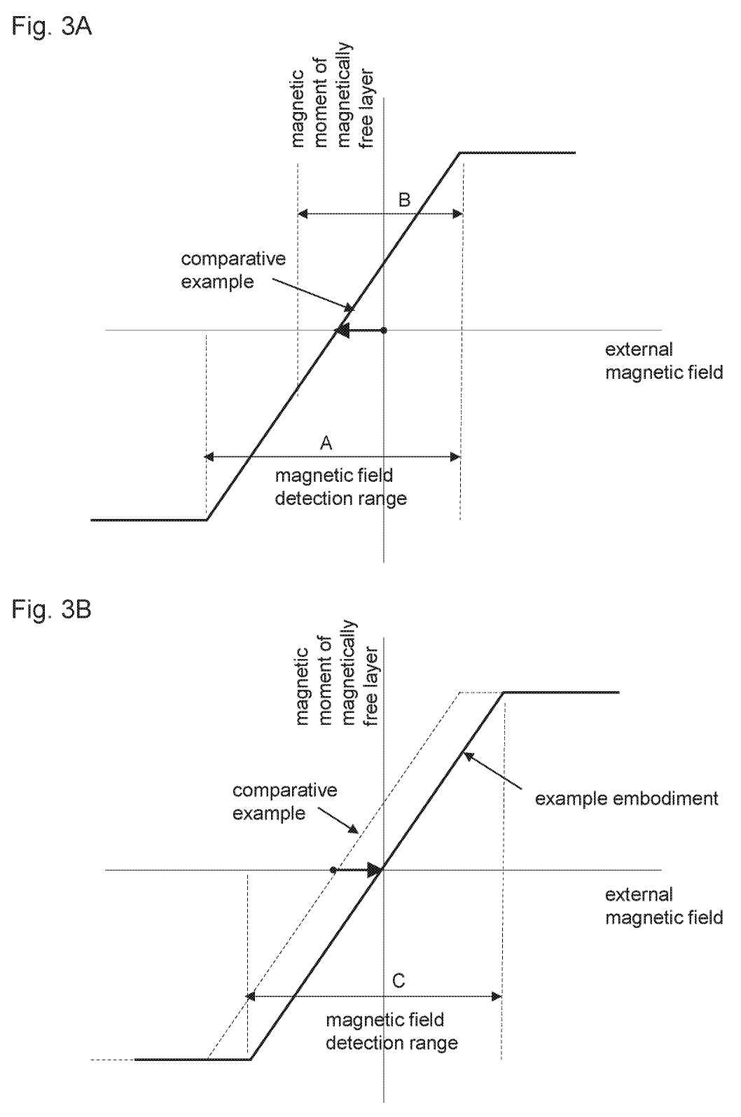

FIG. 3A schematically shows the relationship between an external magnetic field applied to magnetically free layer 45 and the magnetic moment of magnetically free layer 45 of a magnetoresistive element in a comparative example. The magnetic moment of magnetically free layer 45 may be offset in a zero magnetic field state because the average magnetization direction of magnetically free layer 45 may be directed in the +Z-direction due to the orientation of the magnetization direction of core 45A of magnetically free layer 45 in the +Z-direction in the zero magnetic field state. In general, magnetoresistive elements may be used in a region where the magnetization of magnetically free layer 45 is not saturated, and therefore, when an offset occurs, the magnetic field detection range may also be offset as shown by A. However, because the magnetic field detection range is usually set, for example, to be the same on the positive side and the negative side and centered on the zero magnetic field, the magnetic field detection range may narrow as shown by B when an offset occurs.

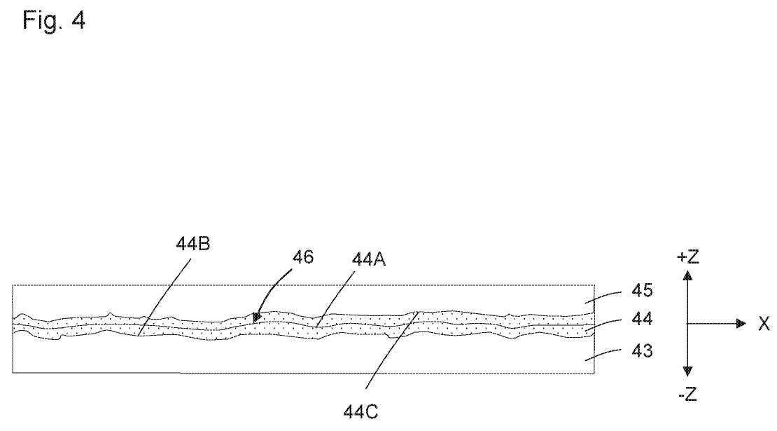

FIG. 4 shows a cross-sectional view of nonmagnetic layer 44 in a cross section parallel to the Z-direction. FIG. 4 also shows a part of magnetically free layer 45 and a part of first magnetically pinned layer 43. The left–right directions of the cross-sectional view are the X-direction. The shape characteristic values of convexo-concave shape 46 of nonmagnetic layer 44 (described below) may be almost the same in any cross section parallel to the Z-direction. Accordingly, the position in the cross-section used to calculate the shape characteristic values is not particularly limited, but in order to ensure calculation accuracy, a position where a certain length in the cross section (described below) can be obtained may be appropriately selected. A cross-sectional view can be obtained, for example, by transmission electron microscopy (TEM).

### Structure of Nonmagnetic Layer 44

In this example embodiment, nonmagnetic layer 44 may have a coarse shape to reduce offset. At least a part of or the entire length of, centerline 44A of nonmagnetic layer 44, the corresponding boundary line 44B between nonmagnetic layer 44 and first magnetically pinned layer 43 and the corresponding boundary line 44C between nonmagnetic layer 44 and magnetically free layer 45 may have mutually similar coarse shapes. In this example embodiment, the coarse shape of centerline 44A in particular is referred to as convexo-concave shape 46. At each point in the X-direction of nonmagnetic layer 44, centerline 44A is a line connecting points equidistant in the Z-direction from boundary line 44B with first magnetically pinned layer 43 and from boundary line 44C with magnetically free layer 45. By convexo-concave shape 46, a magnetic field oriented in the direction opposite to the magnetization direction of first magnetically pinned layer 43 (cancelling magnetic field Hin) may be applied to magnetically free layer 45.

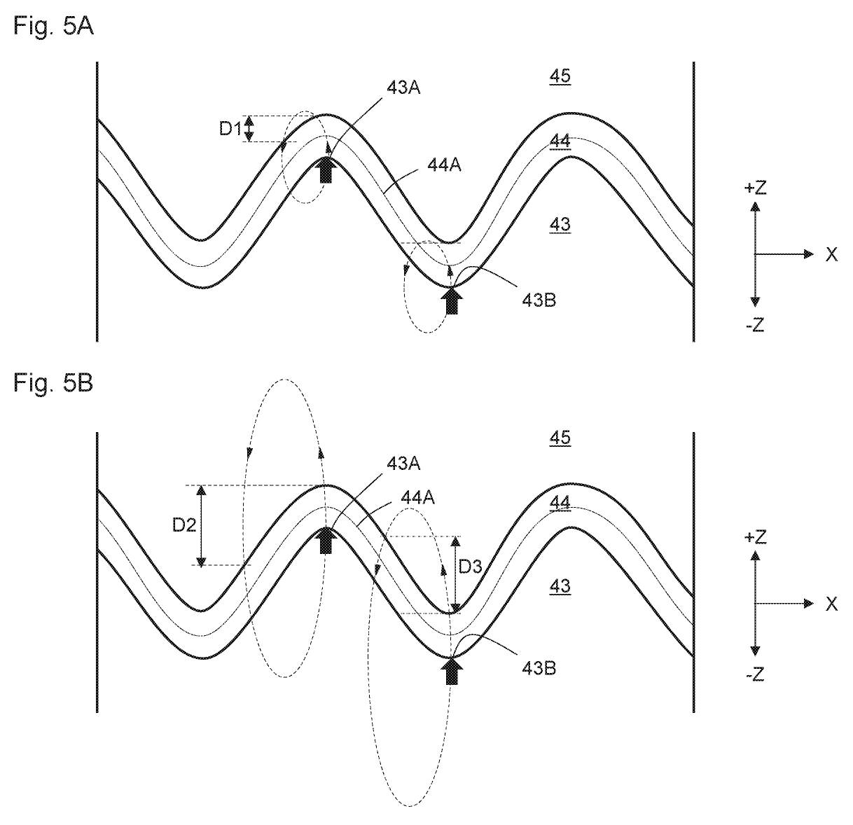

FIGS. 5A–5B are partial enlarged views of first magnetically pinned layer 43, nonmagnetic layer 44, and magnetically free layer 45, and present simplified illustration of the principle of the generation of cancelling magnetic field Hin. For the convenience of explanation, nonmagnetic layer 44 is assumed to have a sinusoidal convexo-concave shape. The dashed lines show magnetic flux. First magnetically pinned layer 43 may be magnetized in the +Z-direction, and, although not shown, core 45A of magnetically free layer 45 may also be magnetized in the +Z-direction.

FIG. 5A illustrates, of magnetic flux that enters and exits first magnetically pinned layer 43, magnetic flux that has a short path. The magnetic flux leaving top part 43A of first magnetically pinned layer 43 may pass through nonmagnetic layer 44, enter magnetically free layer 45, pass through nonmagnetic layer 44 again, and then return to first magnetically pinned layer 43. The magnetic flux leaving bottom part 43B of first magnetically pinned layer 43 may reverse course inside nonmagnetic layer 44 and thus may not enter magnetically free layer 45. Regarding the magnetic flux that leaves top part 43A of first magnetically pinned layer 43 and passes through the interior of magnetically free layer 45, the path length difference D1, which is the path length of the magnetic flux directed in the –Z-direction minus the path length of the magnetic flux directed in the +Z-direction, is positive. The magnetic flux that has a shorter path through the interior of magnetically free layer 45 is therefore believed to affect the magnetization of magnetically free layer 45. In FIG. 5A, the path length difference D1 is shown as a distance in the Z-direction for the convenience of explanation, but the path length difference D1 may also be a difference in the length along the path of the magnetic flux.

FIG. 5B illustrates, of magnet flux that enters and exits first magnetically pinned layer 43, magnetic flux that has a long path. Both the magnetic flux that leaves top part 43A of first magnetically pinned layer 43 and the magnetic flux that leaves bottom part 43B of first magnetically pinned layer 43 may pass through nonmagnetic layer 44, enter magnetically free layer 45, pass through nonmagnetic layer 44 again, and then return to first magnetically pinned layer 43. In the example shown in FIG. 5B, there is little difference between the path length difference D2 of the magnetic flux that leaves top part 43A (the difference between the path length of the magnetic flux directed in the –Z-direction and the path length of the magnetic flux directed in the +Z-direction) and the path length difference D3 of the magnetic flux that leaves bottom part 43B. As a result, in the case of the magnetic flux that has a long path, the influence upon the magnetization of magnetically free layer 45 exerted by the magnetic flux that passes through the interior of magnetically free layer 45 is considered to be small. Considering the magnetic flux that has a short path illustrated in FIG. 5A and the magnetic flux that has a long path illustrated in FIG. 5B, the magnetic flux that has a short path is thought to have a greater effect upon the magnetization of magnetically free layer 45 as a whole. In other words, due to the contribution of the magnetic flux that has a short path, first magnetically pinned layer 43 is believed to cause cancelling magnetic field Hin that is oriented in the direction opposite to the magnetization direction of first magnetically pinned layer 43 to be applied to magnetically free layer 45. As a result, at least a portion of the magnetization of core 45A of magnetically free layer 45 that is directed in the +Z-direction as shown in FIG. 2 may be cancelled by cancelling magnetic field Hin, and the magnetization of magnetically free layer 45 in the +Z-direction is thus weakened in the zero magnetic field state.

In view of the above, a large number of convex portions and concave portions of center line 44A of nonmagnetic layer 44 is believed to produce a large amount of magnetic flux that passes through magnetically free layer 45, resulting in the ability to obtain a relatively strong cancelling magnetic field Hin. As can be understood from FIG. 5A, if both sides of each top parts of centerline 44A drop sharply in the –Z-direction, that is, if the convex portions are steep, the path length differences D1 are believed to be great. Considering these factors, the number of convex portions (density of convex portions) within a certain interval (e.g., within an interval having a certain length in the X-direction) is thought to affect cancelling magnetic field Hin. For example, if center line 44A has a shape having a large number of convex portions within a certain interval (having a high density of convex portions), cancelling magnetic field Hin is believed to be relatively strong. In some cases, the shape of the convex portions is also believed to also affect cancelling magnetic field Hin. For example, if the convex portions in centerline 44A are formed with a steep shape (steeply depressed on both sides of top parts), cancelling magnetic field Hin is believed to be stronger than if the convex portions have a gentle form.

FIG. 3B schematically shows the relationship between the external magnetic field applied to magnetically free layer 45 of magnetoresistive element 3 and the magnetic moment of magnetically free layer 45 of magnetoresistive element 3 according to the present example embodiment. The magnetic moment curve of the comparative example shown in FIG. 3A is shifted to the right by cancelling magnetic field Hin and the offset is thus suppressed. As a result, the magnetic field detection range also moves to the right, enabling the magnetic field detection range to be expanded as shown by C. As can be understood from FIG. 5A, the strength of cancelling magnetic field Hin can be adjusted by convexo-concave shape 46 of nonmagnetic layer 44.

Convexo-concave shape 46 of nonmagnetic layer 44 can be formed by various methods. For example, the surface of the layer below nonmagnetic layer 44 in the direction of stacking (e.g., first magnetically pinned layer 43) can be etched before nonmagnetic layer 44 is formed. The etching of the lower layer may increase the coarseness of the lower layer. Because the surface roughness and surface shape of the lower layer is reflected to some extent in nonmagnetic layer 44, the surface of nonmagnetic layer 44 may also become rougher and coarser. The longer the etching time, the coarser the lower layer becomes, and accordingly, the coarser nonmagnetic layer 44 may become. Another method is to heat (anneal) the lower layer at a high temperature. The higher the heating temperature or the longer the heating time, the coarser the lower layer becomes, and nonmagnetic layer 44 may accordingly become coarser. Heating (annealing) may be performed after nonmagnetic layer 44 is formed. Another method is to form a layer of material (such as Ru, Mn, or alloys containing Mn) whose surface tends to become rougher due to the growth of crystal grains below nonmagnetic layer 44 in the direction of stacking. The thicker this layer, the coarser the layer becomes, and nonmagnetic layer 44 may accordingly become coarser.

### Method for Quantifying the Convexo-Concave Shape 46 at Centerline 44A of Magnetic Layer 44

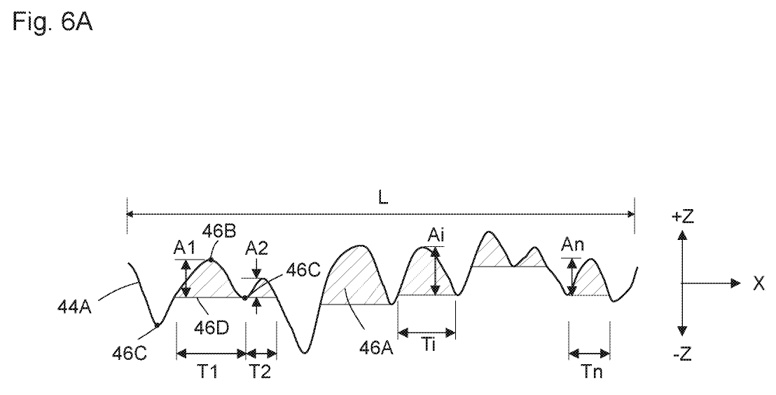

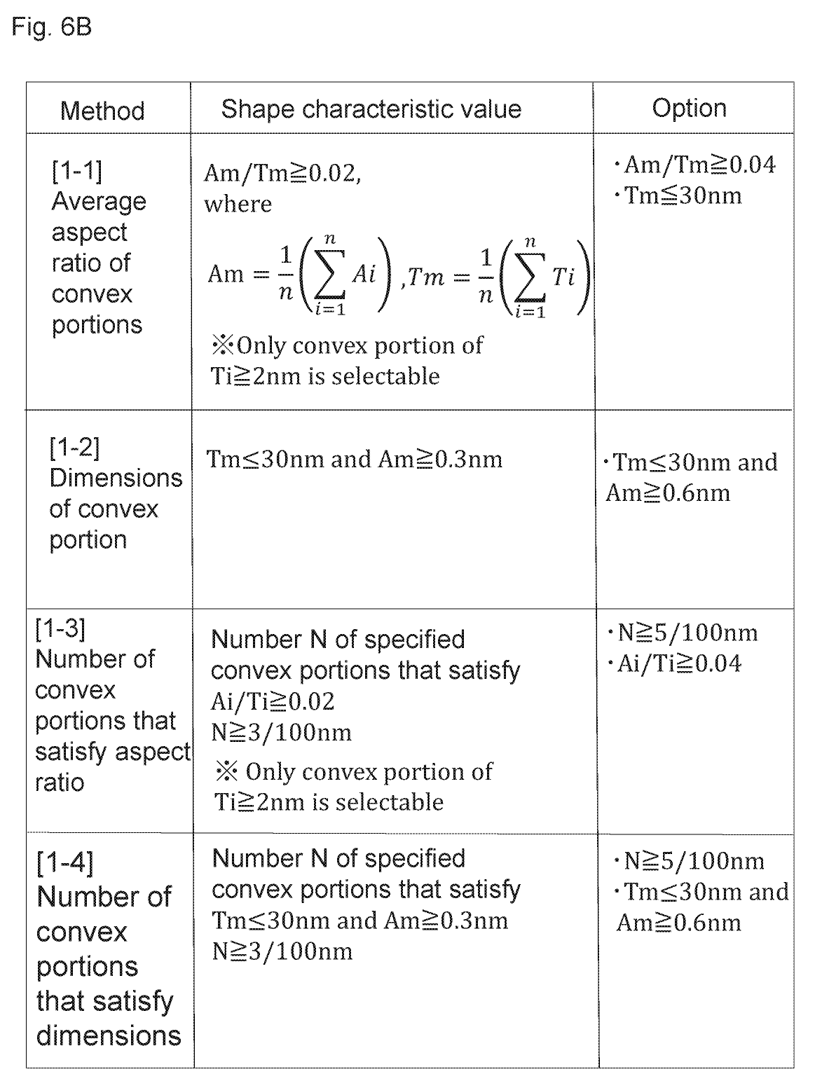

Explanation next regards the method of quantifying convexo-concave shape 46 of centerline 44A of nonmagnetic layer 44, i.e., the method of finding the appropriate shape characteristic values of convexo-concave shape 46. In this way, the shape of convexo-concave shape 46 can be better defined. The shape characteristic values may be obtained for the portion of centerline 44A that is included in target range L (see FIGS. 6A, 7A, 8A and 9A). The length in the X-direction of target range L may be, for example, at least 100 nm, and may be the diameter of, or about half the diameter of, non-magnetic layer 44 as viewed from the Z-direction.

In a first method, as pre-processing for quantification, filter processing can be applied to centerline 44A obtained by TEM observation. Specifically, for example, in order to remove short-wavelength minute coarse components from centerline 44A shown in FIG. 4, filter processing deletes components of wavelengths λs or less. No particular limitation applies to wavelength λs, but in this example embodiment, for example, wavelength λs can be 1 nm. Minute coarse components are components that may cause errors in obtaining appropriate shape characteristic values. Removing the minute coarse components may suppress these errors. Although not required, components having wavelength λc or longer may be cut by filter processing to remove the long-wavelength undulation components of centerline 44A. In this case, the filter processing extracts wavelength components having wavelengths greater than λs but less than λc from centerline 44A shown in FIG. 4. The undulation component may also be a component that can cause errors. Therefore, although not required, removing the undulation component provides greater suppression of errors. FIG. 6A shows filtered centerline 44a compressed in the X-direction.

The first method focuses on convex portions 46A that are parts of convexo-concave shape 46 and that protrude toward magnetically free layer 45. Each convex portion 46A includes, in this case, base 46D and top part 46B that protrudes toward magnetically free layer 45. Base 46D may be a line extending in a direction (the X-direction) perpendicular to the Z-direction from bottom part 46C that is closer to top part 46B in the Z-direction among two bottom parts 46C adjacent to top part 46B on either side of top part 46B. One end of base 46D may be at bottom part 46C that is closer to top part 46B in the Z-direction, and the other end may be at the point where a line drawn in the X-direction from bottom part 46C that is closer to top part 46B intersects with centerline 44A between top part 46B and the other bottom part 46C. FIG. 6A shows in hatching convex portions 46A defined by this description.

FIG. 6B shows several methods for determining the appropriate shape characteristic values of convexo-concave shape 46 of centerline 44A of nonmagnetic layer 44. For each of the n extracted convex portions 46A, lengths T1, T2, ..., Ti, ..., Tn of bases 46D and heights A1, A2, ..., Ai, ..., An of convex portions 46A (the distance in the Z-direction between base 46D and top part 46B) may be obtained from TEM images. Next, average length Tm of bases 46D of convex portions 46A may be obtained as (T1 + T2 + ... + Tn) / n, and average height Am of the convex portions 46A may be obtained as (A1 + A2 + ... + An) / n. In this case, for example, to exclude minute convex portions 46A, only convex portions 46A in which Ti ≥ 2 nm can be selected to obtain average length Tm and average height Am. The widths of the minute convex portions to be excluded are not limited to the above, and a larger value (e.g., 3nm or more) or a smaller value (e.g., 0.5 nm or more, or 1 nm or more) may be selected as appropriate.

As described above, convex portions 46A having steeper shape are considered to contribute more to cancelling magnetic field Hin than convex portions having a nearly flat shape. The shape of convexo-concave shape 46 can therefore be specified, for example, by the average aspect ratio of convex portions 46A (Method 1-1). In this case, the average aspect ratio can be defined as Am/Tm ≥ 0.02, and also as Am/Tm ≥ 0.04. There is no restriction on Tm. For example, by excluding the above-mentioned minute convex portions, average length Tm may be substantially defined as Tm ≥ 2 nm. If relatively large convex portions 46A are selected, Tm will be relatively large (e.g., Tm ≥ 10 nm). If there is a large number of larger convex portions 46A, the number (density) of convex portions 46A per unit length in the X-direction may decrease. Because it is thought that a larger number of convex portions 46A of a certain size may generate larger cancelling magnetic field Hin, average length Tm may be defined as Tm ≤ 30 nm. The shape of convexo-concave shape 46 may be specified by the dimensions of Am and Tm (Method 1-2). In this case, dimensions may be defined as Tm ≤ 30 nm and Am ≥ 0.3 nm, or may be defined as Tm ≤ 30 nm and Am ≥ 0.6 nm.

The shape of convexo-concave shape 46 may be specified by the number of specified convex portions per unit interval in the X-direction (Method 1-3). The specified convex portions can be convex portions 46A in which Ai/Ti ≥ 0.02 or Ai/Ti ≥ 0.04. To exclude minute convex portions 46A, only convex portions 46A in which Ti ≥ 2 nm can be selected as the specified convex portions. The X-direction unit interval may be, for example, an interval of length of 100 nm selected from target range L, but is not limited to 100 nm. The number N of the specified convex portions for each interval 100 nm can be more than 3 or more than 5. The specified convex portions can be defined as convex portions 46A in which Ti ≤ 30 nm and Ai ≥ 0.3 nm (Method 1-4). Alternatively, the specified convex portions can be defined as convex portions 46A in which T ≤ 30 nm and A ≥ 0.6 nm.

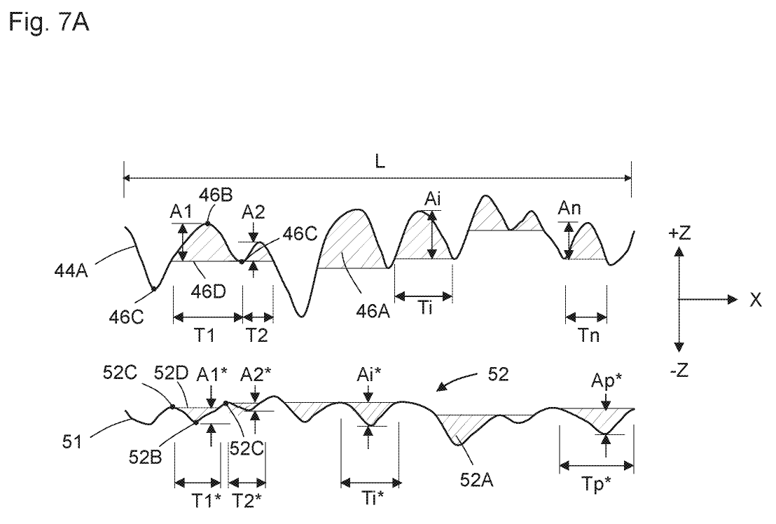

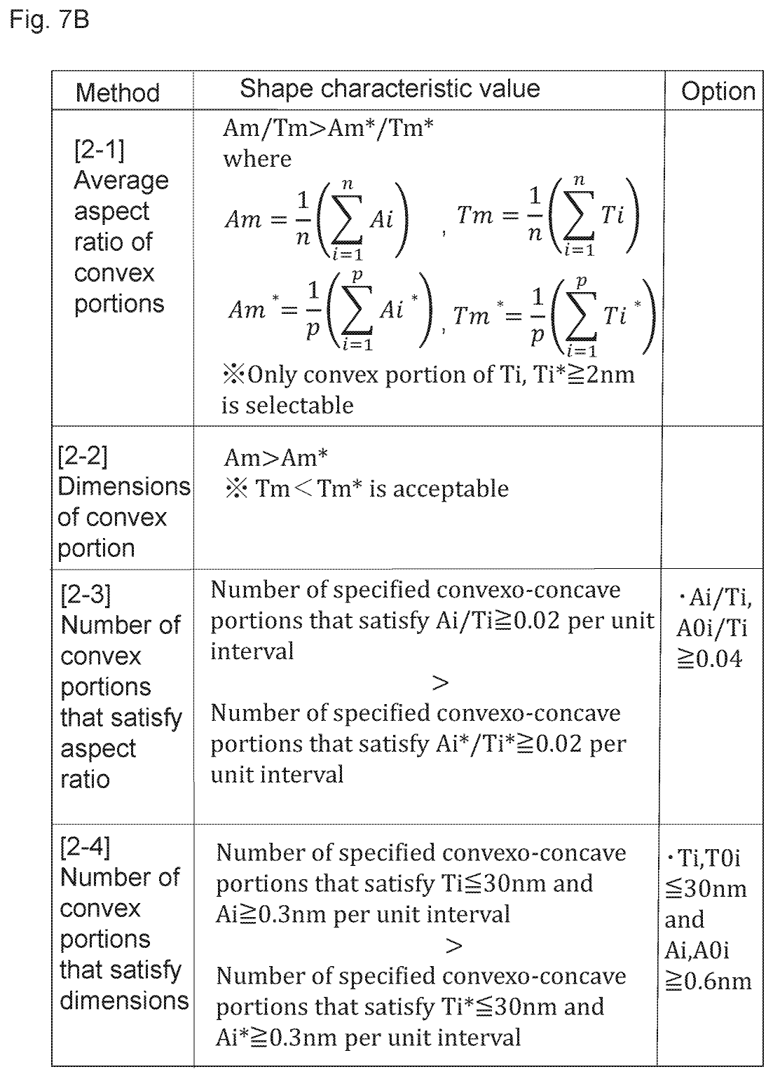

FIGS. 7A–7B show a second method for determining the appropriate shape characteristic values of convexo-concave shape 46 of centerline 44A of nonmagnetic layer 44. In a cross section parallel to the Z-direction, convexo-concave shape 46 of centerline 44A of nonmagnetic layer 44 may be formed to be, for example, rougher than convexo-concave shape 52 of first electrode layer 5 (electrode boundary line 51 shown in FIG. 1) that faces substrate 2. Therefore, in the second method, the roughness of convexo-concave shape 46 may be specified compared to the roughness of convexo-concave shape 52 of electrode boundary line 51. FIG. 7A shows, in a compressed state in the X-direction, centerline 44A and electrode boundary line 51 that have been filtered in the same way as in Method 1. Convexo-concave shape 46 of centerline 44A may have first convex portions 46A. First convex portions 46A may be defined in the same manner as convex portions 46A in Method 1. Convexo-concave shape 52 of electrode boundary line 51 may have second convex portions 52A protruding toward substrate 2. Each second convex portion 52A may include top part 52B and base 52D similarly to first convex portions 46A. Base 52D may be a line extending in the direction (the X-direction) perpendicular to the Z-direction from the bottom part 52C that is closer to top part 52B in the Z-direction among two bottom parts 52C adjacent to top part 52B on either side of top part 52B. One end of base 52D may be at bottom part 52C that is closer to top part 52B in the Z-direction, and the other end may be at the point where a line drawn in the X-direction from bottom part 46C that is closer to top part 52B intersects with electrode boundary line 51 between top part 52B and the other bottom part 52C. FIG. 7A shows in hatching first convex portions 46A and second convex portions 52A.

FIG. 7B shows several methods for determining the shape characteristic values of convexo-concave shape 46 of centerline 44A of nonmagnetic layer 44. According to method 2-1, if the average length of bases 46D of first convex portions 46A is Tm, the average height of first convex portions 46A (the average distance in the Z-direction between base 46D and top part 46B) is Am, the average length of bases 52D of second convex portions 52A is Tm*, and the average height of second convex portions 52A (the average distance in the Z-direction between bases 52D and top part 52B) is Am*, then Am / Tm > Am* / Tm*. According to Method 2-2, Am > Am*. In this case, the average lengths may be defined as Tm < Tm* to increase the density of convex portions in convexo-concave shape 46. In these methods, to exclude minute convex portions 46A and 52A, only convex portions 46A in which Ti ≥2nm and convex portions 52A in which Ti* ≥ 2 nm can be selected to obtain average lengths Tm and Tm* and average heights Am and Am*.

The shape of convexo-concave shape 46 can also be defined by the relationship of the numbers of specified convex portions for each unit interval in the X-direction. According to Method 2-3, when the length of bases 46D of first convex portions 46A is Ti, the height of first convex portions 46A (the distance in the Z-direction between bases 46D and top parts 46B) is Ai, the length of bases 52D of second convex portions 52A is Ti*, and the height of second convex portions 52A (the distance in the Z-direction between bases 52D and top parts 52B) is Ai*, then the number of first convex portions 46A (specified convex portions) in which Ai/Ti ≥ 0.02 per unit length section in the X-direction may be larger than the number of second convex portions 52A (specified convex portions) in which Ai*/Ti* ≥ 0.02 per unit length interval in the X-direction. According to method 2-4, the number per unit length interval in the X-direction of first convex portions 46A (specified convex portions) in which Ti ≤ 30 and Ai ≥ 0.3 nm may be larger than the number per unit length interval in the X-direction of second convex portions 52A (specified convex portions) in which Ti* ≤ 30 and Ai* ≥ 0.3 nm. In these methods, the X-direction unit interval may be, for example, an interval having a length of 100 nm selected from target range L but is not limited to 100 nm. The aspect ratio may be 0.04 instead of 0.02. Alternatively, Ti and Ti* may be 30 nm or less and Ai and Ai* may be 0.6 nm or more.

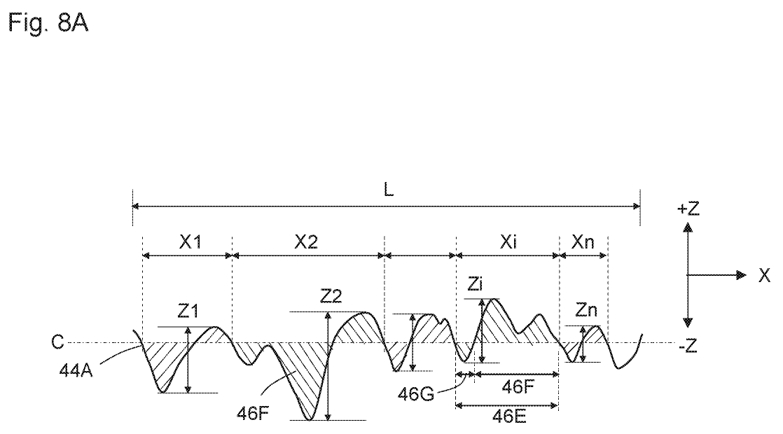

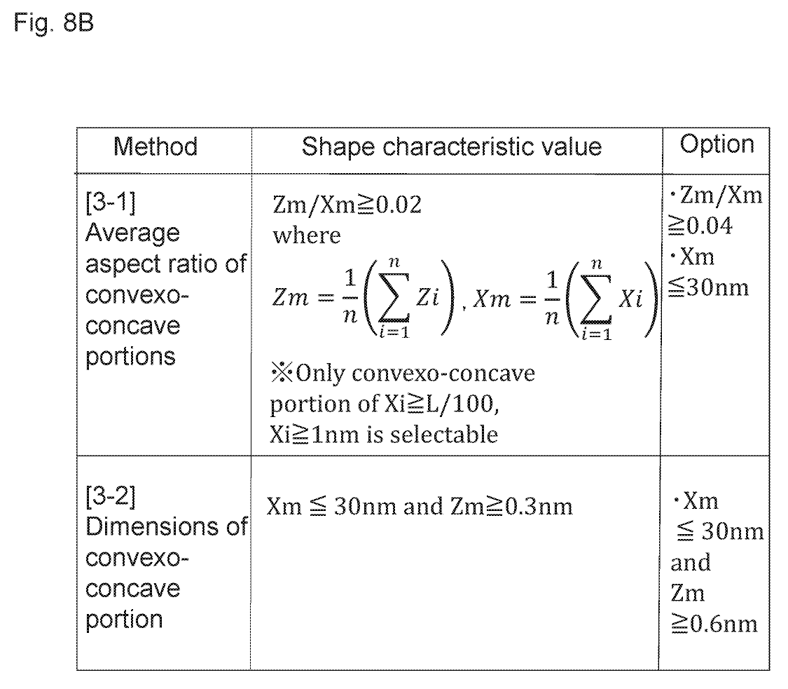

FIGS. 8A–8B show a third method for determining the appropriate shape characteristic values for convexo-concave shape 46 of centerline 44A of nonmagnetic layer 44. FIG. 8A shows centerline 44A in a compressed state in the X-direction. The third method focuses on convexo-concave portions 46E that belong to convexo-concave shape 46. To obtain convexo-concave portions 46E, centerline C of convexo-concave shape 46 may first be obtained. One continuous upper portion of convexo-concave shape 46 divided by centerline C may be ridges 46F, which may also be referred to as protrusions, and one continuous lower portion may be valley 46G, which may also be referred to as a recess. Convexo-concave portion 46E may be a region comprising a pair of adjacent ridges 46F and valley 46G. As centerline C, for example, the average line specified in JIS B 0601-2001 may be used. In this case, centerline C can be obtained, for example, by the least-squares method after considering convexo-concave shape 46 as a curve (a cross-sectional curve at a certain position of nonmagnetic layer 44).

FIG. 8B shows several methods for determining the appropriate shape characteristic values of convexo-concave shape 46 of centerline 44A of nonmagnetic layer 44. According to method 3-1, for each of the n extracted convexo-concave portions 46E, lengths X1, X2, ..., Xi, ..., Xn of convexo-concave portions 46E (dimensions in the X-direction) and heights Z1, Z2, ..., Zi, ..., Zn of convexo-concave portions 46E (dimensions in the Z-direction) may be obtained from TEM images. The height of convexo-concave portions 46E is the Z-direction distance between the points of convexo-concave portions 46E that are closest to magnetically free layer 45 and the points that are farthest away from magnetically free layer 45 in the Z-direction. Next, average length Xm of convexo-concave portions 46E may be obtained as (X1 + X2 + ... + Xn) / n, and average height Zm of convexo-concave portions 46E may be obtained as (Z1 + Z2 + ... + Zn) / n. In this case, for example, minute convexo-concave portions 46E may be excluded. For example, convexo-concave portions 46E whose length is less than a specific percentage (e.g., less than 1%) of target range L may be excluded. For example, convexo-concave portions 46E whose height is less than a specific percentage (e.g., less than 10%) of the maximum height of convexo-concave portions 46E in target range L may be excluded. In FIG. 8A, convexo-concave portions 46H whose length is less than 1% of the length of target range L may be excluded. In this example embodiment, the filter processing of the first and second methods may be omitted. However, if target range L is broad, relatively large convexo-concave portions 46E may be excluded, and as a result, only convexo-concave portions 46E whose length is less than 1% of target range L and less than 1 nm may be excluded. Convex portions 46A having a steep shape are considered to contribute more to cancelling magnetic field Hin than convex portions 46A having a nearly flat shape. Therefore, the dimensions of convex portions 46A may be defined as Zm / Xm ≥ 0.02 or Zm / Xm ≥ 0.04. For the same reasons as in Method 1, the dimensions may be defined as Xm ≤ 30 nm. Convexo-concave shapes 46 can also be specified by the dimensions of Zm and Xm (Method 3-2). In this case, the dimensions may be defined as Xm ≤ 30 nm and Zm ≥ 0.3 nm, or may be defined as Xm ≤ 30 nm and Zm ≥ 0.6 nm.

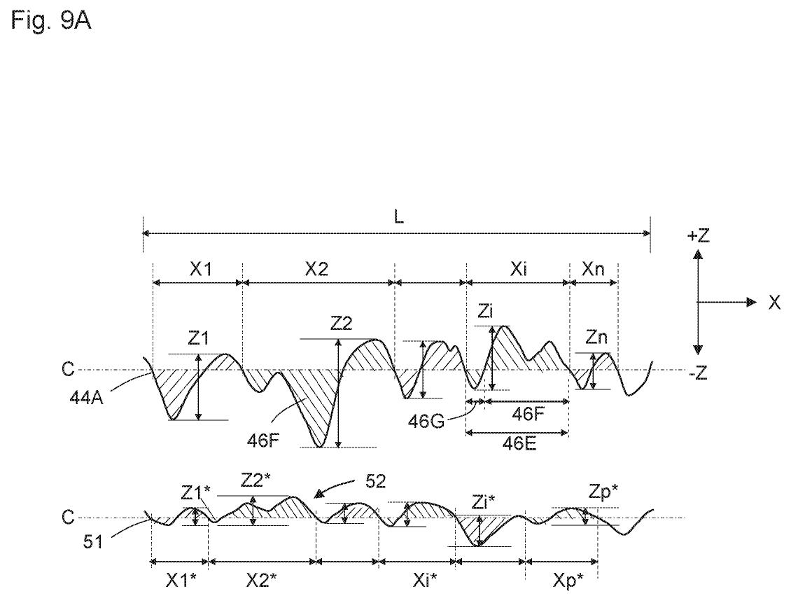

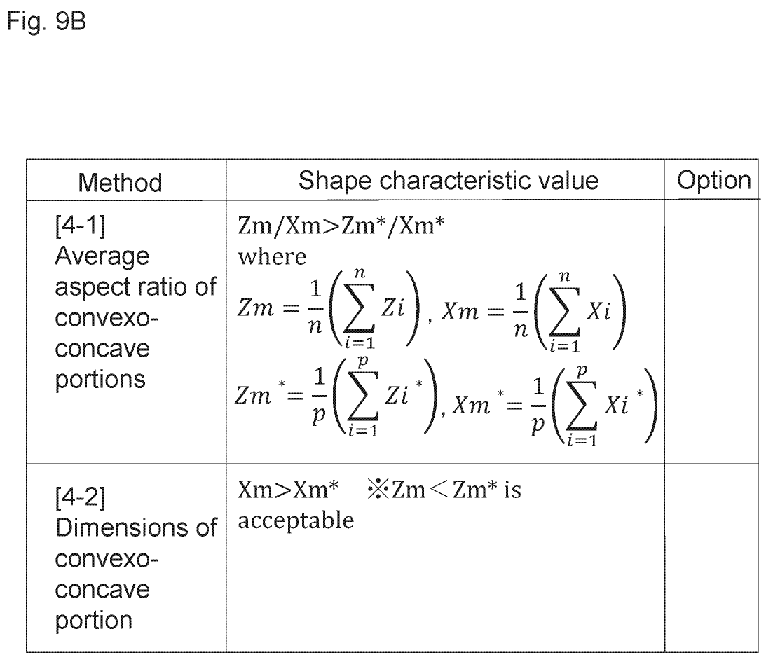

FIGS. 9A–9B show a fourth method for determining the appropriate shape characteristic values for convexo-concave shape 46 of centerline 44A of nonmagnetic layer 44. FIG. 9A shows centerline 44A in a compressed state in the X-direction. In the fourth method, the roughness of convexo-concave shape 46 of centerline 44A may be defined compared to electrode boundary line 51 of first electrode layer 5. Convexo-concave shape 46 of centerline 44A may have first convexo-concave portions 46E. First convexo-concave portions 46E are the same as convexo-concave portions 46E in Method 3 and may be defined in the same manner as convexo-concave portions 46E. Electrode boundary line 51 may have second convexo-concave portions 52E each comprising a pair of ridges and a valley adjacent to each other. Second concavo-convex portions 52E may be defined in the same manner as first convexo-concave portions 46E.

FIG. 9B shows several methods for determining appropriate shape characteristic values for convexo-concave shape 46 of centerline 44A of nonmagnetic layer 44. According to method 4-1, if the average length in the X-direction of first convexo-concave portions 46E is Xm, the average height in the Z-direction of first convexo-concave portions 46E is Zm, the average length in the X-direction of second convexo-concave portions 52E is Xm*, and the average height in the Z-direction of the plurality of second convexo-concave shapes 52E is Zm*, then the average height in the Z-direction of second convexo-concave portions 52E is Zm*, Zm / Xm > Zm* / Xm*. According to Method 4-2, Zm > Zm*. In order to increase the density of convex portions in convexo-concave shape 46, the dimensions may be defined as Xm < Xm*.

According to the present disclosure, a magnetoresistive element can be provided that has a magnetically free layer that is magnetized in a vortex shape and a magnetically pinned layer whose magnetization direction is fixed in the film thickness direction, and in which the offset of the magnetic moment of the magnetically free layer is suppressed in the absence of an external magnetic field.

The technology according to the present disclosure has been explained with reference to the above example embodiments. The technology according to the present disclosure is not limited to the specific examples described above, and various aspects and variations of the technology according to the present disclosure can be implemented based on the above description.

### EXPLANATION OF REFERENCE NUMERALS

1 magnetic sensor

2 substrate

3 magnetoresistive element

4 magnetic field detector

5, 6 first and second electrode layers

43 first magnetically pinned layer (magnetically pinned layer)

44 nonmagnetic layer

44A centerline of nonmagnetic layer

45 magnetically free layer

46 convexo-concave shape

46A convex portion

46B top part

46C bottom part

46D base

46E convexo-concave portion (first convexo-concave portion)

51 electrode boundary line

52E second convexo-concave portion

Z first direction

1. A magnetoresistive element comprising a magnetically free layer, a magnetically pinned layer, and a nonmagnetic layer arranged in a first direction, wherein
the magnetically free layer is magnetized in a vortex shape,
a magnetization direction of the magnetically free layer is variable according to external magnetic field,
a magnetization direction of the magnetically pinned layer is fixed in the first direction,
the nonmagnetic layer is located between the magnetically free layer and the magnetically pinned layer, and
at least a part of a centerline of the nonmagnetic layer has a convexo-concave shape in a cross section parallel to the first direction.

2. The magnetoresistive element according to claim 1, wherein
the convexo-concave shape has convex portions that protrude toward the magnetically free layer,
each of the convex portions includes a top part and a base,
the base extends in a direction perpendicular to the first direction from a bottom part that is closer to the top part in the first direction among two bottom parts adjacent to the top part on either side of the top part, and
Am/Tm ≥ 0.02, where Tm is an average length of the bases of the convex portions and Am is an average height of the convex portions.

3. The magnetoresistive element according to claim 1, wherein
the convexo-concave shape has convex portions that protrude toward the magnetically free layer,
each of the convex portions includes a top part and a base,
the base extends in a direction perpendicular to the first direction from a bottom part that is closer to the top part in the first direction among two bottom parts adjacent to the top part on either side of the top part, and
Tm ≤ 30nm and Am ≥ 0.3nm, where Tm is an average length of the bases of the convex portions and Am is an average height of the convex portions.

4. The magnetoresistive element according to claim 1, wherein
the convexo-concave shape has convex portions that protrude toward the magnetically free layer,
each of the convex portions includes a top part and a base,
the base extends in a direction perpendicular to the first direction from a bottom part that is closer to the top part in the first direction among two bottom parts adjacent to the top part on either side of the top part, and
three or more convex portions each having a base length T and a height A such that A / T ≥ 0.02, are disposed for each section having a length of 100 nm.

5. The magnetoresistive element according to claim 1, wherein
the convexo-concave shape has convex portions that protrude toward the magnetically free layer,
each of the convex portions includes a top part and a base,
the base extends in a direction perpendicular to the first direction from a bottom part that is closer to the top part in the first direction among two bottom parts adjacent to the top part on either side of the top part, and
three or more convex portions each having a base length T and a height A such that T ≤ 30 nm and A ≥ 0.3 nm, are disposed for each section having a length of 100 nm.

6. The magnetoresistive element according to claim 1, wherein
the convexo-concave shape has convexo-concave portions comprising a pair of ridges and a valley adjacent to each other, and
Zm / Xm ≥ 0.02, where Xm is an average length of the convexo-concave portions in a direction perpendicular to the first direction and Zm is an average height of the convexo-concave portions in the first direction.

7. The magnetoresistive element according to claim 1, wherein
the convexo-concave shape has convexo-concave portions comprising a pair of ridges and a valley adjacent to each other, and
Xm ≤ 30 nm and Zm ≥ 0.3 nm, where Xm is an average length in a direction perpendicular to the first direction of the convexo-concave portions and Zm is an average height in the first direction of the convexo-concave portions.

8. A magnetoresistive element comprising a magnetically free layer, a magnetically pinned layer, and a nonmagnetic layer arranged in a first direction, wherein
the magnetically free layer is magnetized in a vortex shape,
a magnetization direction of the magnetically free layer is variable according to external magnetic field,
a magnetization direction of the magnetically pinned layer is fixed in the first direction,
the nonmagnetic layer is located between the magnetically free layer and the magnetically pinned layer, and
the magnetically pinned layer applies to the magnetically free layer a magnetic field in a direction opposite to a magnetization direction of a center of the vortex shape of the magnetically free layer.

9. The magnetoresistive element according to claim 1, wherein the nonmagnetic layer is an insulating layer.

10. A magnetic sensor comprising the magnetoresistive element according to claim 1.

11. A magnetic sensor comprising a substrate and the magnetoresistive element according to claim 1, wherein
the magnetoresistive element has an electrode layer and a magnetic field detector comprising the magnetically free layer, the nonmagnetic layer, and the magnetically pinned layer,
the electrode layer is disposed between the substrate and the magnetic field detector and is electrically connected to the magnetic field detector,
in a cross section parallel to the first direction, at least a part of a boundary line of the electrode layer that faces the substrate has a convexo-concave shape, and
the convexo-concave shape of a centerline of the non-magnetic layer is coarser than the convexo-concave shape of the boundary line of the electrode layer.

12. The magnetic sensor according to claim 11, wherein
the convexo-concave shape of the centerline comprises first convex portions that protrude toward the magnetically free layer,
the convexo-concave shape of the boundary line comprises second convex portions that protrude toward the substrate,
each of the first convex portions and each of the second convex portions includes a top part and a base,
the base extends in a direction perpendicular to the first direction from a bottom part that is closer to the top part in the first direction among two bottom parts adjacent to the top part on either side of the top part, and
Am / Tm > Am* / Tm*, where Tm is an average length of the bases of the first convex portions, Am is an average height of the first convex portions, Tm* is an average length of the bases of the second convex portions, and Am* is an average height of the second convex portions.

13. The magnetic sensor according to claim 11, wherein
the convexo-concave shape of the centerline comprises first convex portions that protrude toward the magnetically free layer,
the convexo-concave shape of the boundary line comprises second convex portions that protrude toward the substrate,
each of the first convex portions and each of the second convex portions includes a top part and a base,
the base extends in a direction perpendicular to the first direction from, of two bottom parts adjacent to the top part on either side of the top part, a bottom part that is closer to the top part in the first direction, and
Am > Am* and Tm < Tm*, where Tm is an average length of the bases of the first convex portions, Am is an average height of the first convex portions, Tm* is an average length of the bases of the second convex portions, and Am* is an average height of the second convex portions.

14. The magnetic sensor according to claim 11,
wherein
the convexo-concave shape of the centerline comprises first convex portions that protrude toward the magnetically free layer,
the convexo-concave shape of the boundary line comprises second convex portions that protrude toward the substrate,
each of the first convex portions and each of the second convex portions are includes a top part and a base that extends in a direction perpendicular to the first direction from a bottom part that is closer to the top part in the first direction among two bottom parts adjacent to the top part on either side of the top part,, and
the number of the first convex portions in which A / T ≥ 0.02 per unit length section is greater than the number of the second convex portions in which A* / T* ≥ 0.02 per unit length section, where T is a length of the bases of the first convex portions, A is a height of the first convex portions, T* is a length of the bases of the
second convex portions, and A* is a height of the second convex portions.

15. The magnetic sensor according to claim 11, wherein
the convexo-concave shape of the centerline comprises first convex portions that protrude toward the magnetically free layer,
the convexo-concave shape of the boundary line comprises second convex portions that protrude toward the substrate,
each of the first convex portions and each of the second convex portions includes a top part and a base that extends in a direction perpendicular to the first direction from a bottom part that is closer to the top part in the first direction among two bottom parts adjacent to the top part on either side of the top part,, and
the number of the first convex portions in which T ≤ 30 nm and A ≥ 0.3 nm per unit length section is greater than the number of the second convex portions in which T* ≤ 30 nm and A* ≥ 0.3nm per unit length section, where T is a length of the bases of the first convex portions, A is a height of the first convex portions, T* is a length of the bases of the second convex portions, and A* is a height of the second convex portions.

16. The magnetic sensor according to claim 11, wherein
the convexo-concave shape of the centerline has first convexo-concave portions comprising a pair of ridges and a valley adjacent to each other,
the convexo-concave shape of the border line has second convexo-concave portions comprising a pair of ridges and a valley adjacent to each other, and
Zm / Xm > Zm* / Xm*, where Xm is an average length of the first convexo-concave portions in a direction perpendicular to the first direction, Zm is an average height of the first convexo-concave portions in the first direction, Xm* is an average length of the second convexo-concave portions in a direction perpendicular to the first direction, and Zm* is an average height of the second convexo-concave portions in the first direction.

17. The magnetic sensor according to claim 11, wherein
the convexo-concave shape of the centerline has first convexo-concave portions comprising a pair of ridges and a valley adjacent to each other,
the convexo-concave shape of the border line has second convexo-concave portions comprising a pair of ridges and a valley adjacent to each other, and
Zm > Zm* and Xm < Xm*, where Xm is an average length of the first convexo-concave portions in a direction perpendicular to the first direction, Zm is an average height of the first convexo-concave portions in the first direction, Xm* is an average length of the second convexo-concave portions in a direction perpendicular to the first direction, and Zm* is an average height of the second convexo-concave portions in the first direction.
